(19) United States
(12) Patent Application Publication
(10) Pub. No.: US 2004/0032029 A1
(43) Pub. Date: Feb. 19, 2004

(54) Semiconductor device and its production method

(76) Inventor: Takamasa Tanikuni, Kanagawa (JP)

Correspondence Address: Darryl G. Walker, WALKER & SAKO, LLP, Suite 235, 300 South First Street, San Jose, CA, 95113, US

(21) Appl. No.: 10/636,046

(22) Filed: Aug. 7, 2003

(30) Foreign Application Priority Data
Aug. 19, 2002 (JP) 2002-237734

(51) Int. Cl. H01L 23/48; H01L 23/52; H01L 29/40

(52) U.S. Cl. 257/762; 257/751

(57) ABSTRACT

A semiconductor device (10) and its production method,is disclosed in which a cap film for a wiring made of copper or a copper alloy may prevent or reduce stress corrosion cracking in the wiring. A semiconductor device (10) may include a wiring (11) made of copper or a copper alloy including a barrier film (12) formed between the wiring (11) and a cap film (13) for preventing copper diffusion. The barrier film (12) may include a SiC film to provide an exposure prevention film, which prevents the wiring (11) from being exposed to a film forming gas for the cap film (13), which includes a SiCN film.

### TECHNICAL FIELD

The present invention relates generally a semiconductor device and its production method, and more particularly semiconductor device including a multilayer wiring structure provided with a plurality of layers of copper (Cu) wiring and its production method.

### BACKGROUND OF THE INVENTION

To prevent copper (Cu) from diffusing from a copper wiring to an oxide film used as an interlayer insulating film, a conventional semiconductor device includes a diffusion preventing film.

A cap film is provided on an upper surface of the copper wiring as such a diffusion preventing film. This cap film has been formed by a plasma nitride film such as silicon nitride (SiN). But SiN can be a cause of an increased wiring delay due to having a high permittivity thereby increasing wiring capacitance. In order to address the wiring delay problem, a film material can be changed from SiN to a compound of silicon and carbon (SiC) or a compound of silicon, carbon, and nitrogen (SiCN) having a low permittivity.

Referring now to FIG. 3, a cross sectional view showing a copper wiring formed from a conventional process with a dual damascene method is set forth. Copper wiring 1 is embedded in an interlayer insulating film 2. A cap film 3 is formed thereon for prevention of Cu diffusion. The upper surface of copper wiring 1 is then covered with an interlayer insulating film 4. An interlayer insulating film 6 is then formed over the interlayer insulating film 4.

A via hole is then formed through interlayer insulating film 6, etching stopper film 5, interlayer insulating film 4, and cap film 3 to the upper surface of the copper wiring 1. The via hole is then filled with resist 7. A resist mask 9 used to form a trench 8 on an upper surface of the interlayer insulating film 6.

Japanese Patent Application No. 2001-284355 discloses an example in which a SiC film is used as a cap film. However, if a SiC film is used as cap film 3 for prevention of Cu diffusion or the etching stopper film 5, the resist mask 9 does not obtain an accurate opening shape because contaminated photoresist is produced, thereby precluding accurate exposure. In this way, a low yield ratio of the via results.

The contaminated photoresist is produced because a gas is separated from SiC which is a component of the cap film 3 and the etching stopper film 5. The gas emerges from the upper surface of the interlayer insulating film 6 through the via hole and exercises an adverse effect on the resist mask 9. Due to the effect of the separated gas, sloping shoulders result at the end portions of the resist mask 9 as shown in FIG. 3. The resist mask 9 is preferably cut vertically under normal circumstances.

Furthermore, the film material of SiC cannot obtain an adequate strength. Without an adequate film material strength, pin holes are likely to occur. In this way, diffusion of Cu into the interlayer insulating film cannot be perfectly prevented.

Japanese Patent Publication Laid-open 2002-83869 and Japanese Patent Publication Laid-open 2002-83870 disclose a cover film using SiCN for the copper wiring.

The advantage of using a SiCN film as the cap film 3 for the copper wiring 1 is that an adequate film material strength can be obtained. Thus, the film material is stabilized and pin holes are rare. Also, the photoresist is not contaminated due to the separated gas.

FIGS. 4(a) and 4(b) are schematic sectional views showing a conventional method of forming a cap film provided on copper wiring.

As shown in FIG. 4(a), the copper wiring 1 disposed in the interlayer insulation film 2 has an upper surface that is planarized by CMP (chemical mechanical polishing). A trimethylsilane gas, NH₃ gas (ammonia gas) and He gas, which are gases used in forming the SiCN film, are introduced into a CVD device to stabilize gas pressure. After that, a radio frequency (RF) is introduced. In this way, the SiCN film is formed as the cap film 3 for prevention of Cu diffusion on the upper surface of the copper wiring as illustrated in FIG. 4(b).

However, because the compound is produced with silicon (Si), carbon (C), and nitrogen (N) in forming the SiCN film, the NH₃ gas must be used as a source gas of N. This NH₃ gas has an adverse effect on the copper wiring.

In other words, during the formation of the SiCN film, the copper wiring is exposed to the NH₃ gas when the gas pressure is stabilized before the RF is introduced. Thus, “stress corrosion cracking” occurs, i.e., cracks are caused in a metal due to an interaction between tensile stress and corrosion. It is known that the “stress corrosion cracking” is caused by a combination of copper or a copper alloy and an ammonia-based gas or an amine-based organic matter.

If a cracked portion of the copper wiring grows larger due to “stress corrosion cracking”, a hole is formed and the resistance value of the wiring varies or increases. The wiring can become broken if a crack caused in a connection portion between the copper wiring and the via becomes excessively large.

In light of the above, it would be desirable to provide a semiconductor device and its production method in which a cap film for a wiring made of copper or a copper alloy does not cause stress corrosion cracking in the wiring, or reduces such stress corrosion cracking.

### SUMMARY OF THE INVENTION

According to the embodiments, a semiconductor device and its production method in which a cap film for a wiring made of copper or a copper alloy may prevent or reduce stress corrosion cracking in the wiring has been disclosed. A semiconductor device may include a wiring made of copper or a copper alloy including a barrier film formed between the wiring and a cap film for preventing copper diffusion. The barrier film may include a SiC film to provide an exposure prevention film, which prevents the wiring from being exposed to a film forming gas forming the cap film, which includes a SiCN film.

According to the embodiments, a semiconductor device may include a wiring structure in which an upper surface of a wiring made of copper or a copper alloy may be covered with an insulation film. A barrier film may be formed covering the upper surface of the wiring and between a cap film for preventing copper diffusion and the wiring.

According to another aspect of the embodiments, the barrier film may be an exposure prevention film, which prevents the wiring from being exposed to a film forming gas forming the cap film.

According to another aspect of the embodiments, the barrier film may include a SiCN film.

According to another aspect of the embodiments, the SiCN film may be a film formed by using a trimethylsilane gas, NH₃ gas, and a He gas.

According to one aspect of the embodiments, the barrier film may be a film formed without using NH₃ gas.

According to another aspect of the embodiments, the barrier film may include a SiC film.

According to another aspect of the embodiments, the semiconductor device may include a multilayer wiring structure. The multilayer wiring structure may include a plurality of wiring layers made of copper or a copper alloy and formed with each wiring layer separated by are respective interlayer insulation film.

According to another aspect of the embodiments, a method of producing a semiconductor device having a wiring structure in which an upper surface of a wiring made of copper or a copper alloy is covered with an insulation film may include the step of forming a cap film for prevention of copper diffusion between the wiring and the insulation film over a barrier film covering the upper surface of the wiring.

According to another aspect of the embodiments, a step of forming the barrier film after the wiring film is formed may not include using a NH₃ gas.

According to one aspect of the embodiments, the barrier film may include a SiC film.

According to another aspect of the embodiments, the step of forming the cap film may include using a trimethylsilane gas, NH₃ gas, and He gas after the barrier film is formed.

According to another aspect of the embodiments, the cap film may be formed by introducing the NH₃ gas after the barrier film is formed by using the trimethylsilane gas and He gas.

According to another aspect of the embodiments, the cap film may include a SiCN film.

According to another aspect of the embodiments, the barrier film and the cap film may be formed after the wiring is formed. A method of producing the semiconductor device may include the steps of a series of processes for forming layers of wirings, each layer of wiring covered by an interlayer insulation film and including a step of forming a cap film for prevention of copper diffusion over a barrier film covering an upper surface of the wiring layer.

According to another aspect of the embodiments, a method of producing a semiconductor device may include the steps of forming a first wiring layer made of copper or a copper ally within a first interlayer insulation film, forming a first barrier film over an upper surface of the first wiring layer, forming a first cap film for preventing copper diffusion over the first barrier film, and forming a second interlayer insulation film over the first cap film.

According to another aspect of the embodiments, the step of forming the first barrier film may not include using a NH₃ gas.

According to another aspect of the embodiments, the first barrier film may include a SiC film and the first cap film may include a SiCN film.

According to another aspect of the embodiments, the step of forming the first cap film may include using a trimethylsilane gas, NH₃ gas, and He gas after the first barrier film is formed.

According to another aspect of the embodiments, the first cap film may be formed by introducing the NH₃ gas after the first barrier film is formed by using the trimethylsilane gas and He gas.

According to another aspect of the embodiments, a method of producing a semiconductor device may include the steps of forming a second wiring layer made of copper or a copper ally within a third interlayer insulation film formed over a second interlayer insulation film, forming a second barrier film over an upper surface of the second wiring layer, forming a second cap film for preventing copper diffusion over the second barrier film, and forming a fourth interlayer insulation film over the second cap film.

### BRIEF DESCRIPTION OF THE DRAWINGS

FIG. 1 is a sectional view of a portion of a semiconductor device with a copper wiring according to an embodiment of the present invention.

FIGS. 2(a), 2(b), and 2(c) are sectional views showing a method of forming a cap film provided on a copper wiring according to the embodiment of FIG. 1.

FIG. 3 is a sectional view showing a copper wiring formed from a conventional process with a dual damascene method.

FIGS. 4(a) and 4(b) are sectional views showing a conventional method of forming a cap film provided on copper wiring.

### DETAILED DESCRIPTION OF THE EMBODIMENTS

Various embodiments of the present invention will now be described in detail with reference to a number of drawings.

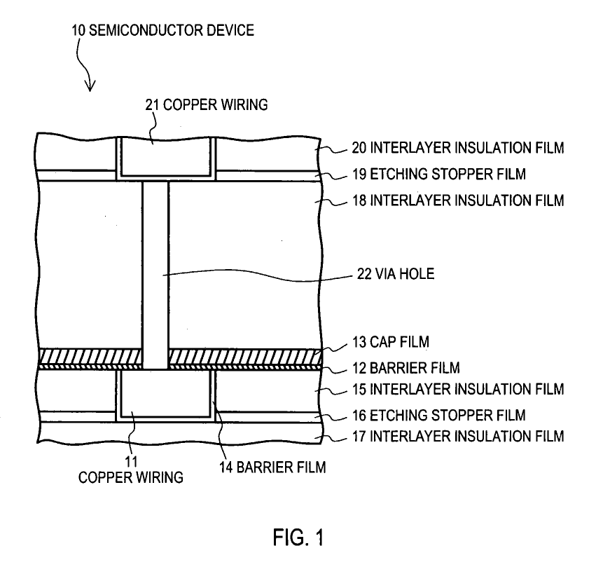

Referring now to FIG. 1 a sectional view of a portion of a semiconductor device with a copper wiring according to an embodiment is set forth and given the general reference character 10. Semiconductor device 10 may include a multilayer wiring structure. The multilayer wiring structure may be provided with a plurality of layers of wiring made of copper (Cu) or a copper alloy (hereinafter, referred to as copper wiring).

An etching stopper film 16 may be formed on an interlayer insulation film 17. An interlayer insulation film 15 may be formed on etching stopper film 16. Interlayer insulation film 15 and etching stopper film 16 may be etched to form a groove. A barrier film 14 may be formed in the groove. Barrier film 14 may be made of tantalum (Ta) or tantalum nitride (TaN), as just two examples. A copper wiring 11 may be formed on barrier film 14 such that barrier film 14 is on a lower surface and side surfaces of copper wiring 11. In this way, copper wiring 11 and barrier film 14 may fill a groove in interlayer insulation film 15 and etching stopper film 16.

A barrier film 12 may be formed on an upper surface of copper wiring 11 and interlayer insulation film 15. A cap film 13 may be formed on an upper surface of barrier film 12. Cap film 13 may prevent Cu diffusion. In this way, the upper surface of copper wiring 11 may be covered with two films, i.e., barrier film 12 and cap film 13.

An interlayer insulating film 18 may be formed on an upper surface of cap film 13. A via hole 22 may be formed through interlayer insulating film 18, cap film 13 and barrier film 12 to copper wiring 11. Via hole 22 may be filled with a suitable conductive material. An etching stopper film 19 may be formed on interlayer insulation film 18. An interlayer insulation film 20 may be formed on etching stopper film 19. Interlayer insulation film 20 and etching stopper film 19 may be etched to form a groove. A copper wiring 21 may be formed to fill a groove in interlayer insulation film 20 and etching stopper film 19. Copper wiring 21 may include a barrier film formed on side surfaces and a bottom surface. Copper wiring 21 may be electrically connected to copper wiring 11 through via hole 22 penetrating interlayer insulation film 18.

Cap film 13 for prevention of Cu diffusion may be formed from a SiCN film with a trimethylsilane gas, He gas and NH₃ gas (ammonia gas). Barrier film 12 may be formed by forming a SiC film with a trimethylsilane gas and He gas. In this way, a SiCN film may be provided over the surface of copper wiring 11 via a SiC film.

The SiC film and the SiCN film may separately appear by film thickness measurements carried out in an optical method. In this way, the SICN film formed using a NH₃ gas may be cumulated on a SiC film formed without using a NH₃ gas.

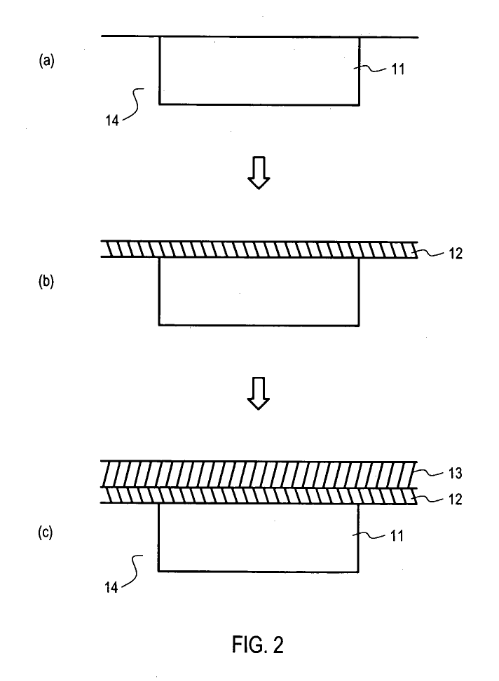

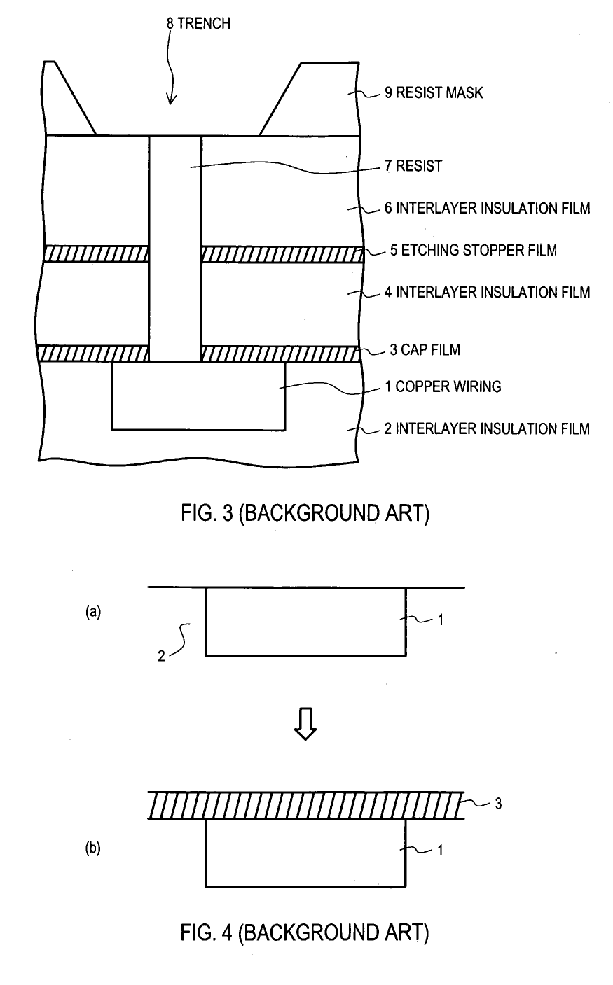

Referring now to FIGS. 2(a), 2(b), and 2(c), sectional views showing a method of forming a cap film provided on a copper wiring according to the embodiment of FIG. 1 is set forth.

As illustrated in FIG. 2(a), an upper surface of copper wiring 11 in interlayer insulation film 14 may be planarized by CMP (chemical mechanical polishing).

Next, as illustrated in FIG. 2(b), in a single-type film forming device, a trimethylsilane gas and He gas, which are gases to form the SiC film, may be introduced to stabilize gas pressure. Then, an RF may be introduced. In this way, the SiC film may be formed as the barrier film 12 on an upper surface of copper wiring 11.

Then, as illustrated in FIG. 2(c), after the SiC film is formed, an NH₃ gas may be continuously introduced without cutting off the RF. In this way, the SiCN film may be formed as the cap film 13 on an upper surface of the SiC film.

More specifically, first a barrier film 12 including a SiC film, which is not formed with an NH₃ gas (which can have an adverse affect on copper wiring 11), is formed on copper wiring 11. Then, cap film 13 for prevention of Cu diffusion may be formed on barrier film 12.

In this way, copper wiring 11 is not exposed to NH₃ gas that can have an adverse effect on copper wiring 11 when cap film 13 is formed using an NH₃ gas, which can be necessary to form a SiCN film of suitable quality. Barrier film 12 may function as an exposure prevention film to prevent copper wiring 11 from being exposed to a gas used in forming cap film 13.

In one approach to forming a cap film 13 as described above, a SiCN film may be formed on an upper surface of a SIC film as follows. After the SiC film as a barrier film 12 is formed on an upper surface of a copper wiring 11 (see FIG. 2(b)), a trimethylsilane gas and He gas, which are gases used to form the SiC film, are discharged from a CVD device. Then, after the discharge of the trimethylsilane gas and He gas, the trimethylsilane gas and He gas are introduced anew along with a NH₃ gas to form the SiCN film.

However, if the film forming process is continuously carried out without any discharge as described above, the film, can be formed with little change in film forming conditions. Moreover, the SiCN film may be continuously cumulated. Thus, such a continuous approach may be more suitable for mass production.

After barrier film 12 and cap film 13 are formed on copper wiring 11, an interlayer insulation film 18 may be formed as illustrated in FIG. 1. Then a series of processes to form a copper wiring 21 may be carried out including steps for forming a barrier film, cap film, and interlayer insulation film. In this way, the processes to form a copper wiring, a barrier film, cap film, and interlayer insulation film may be repeated one or more times in a manner as described in the above-mentioned processes for forming copper wiring 11, barrier film 12, and cap film 13. In this way, a semiconductor device 10 having a multilayer wiring structure including a plurality of copper wiring may be formed.

Additionally, Japanese Patent Application 2002-83870 discloses an example in which SiCN as a cap film is formed with SiH₄, C₂H₄, and N₂ as precursors. But in this case, it is necessary to use NH₃ as the source gas in order to form the SiCN film containing a proper amount of N with low permittivity and a high degree of copper prevention.

According to the embodiments, a SiC film, which is not formed with NH₃ gas as a film forming gas, may be formed before a cap film 13 is formed over a surface of a copper wiring 11. Such a cap film 13 can include a SiCN film for prevention of Cu diffusion. In this way, a barrier film 12, including a SIC film, can be provided between the copper wiring 11 and the cap film 13. Due to the barrier film 12 covering an upper surface of the copper wiring 11, the copper wiring 11 and the cap film 13 for prevention of copper diffusion may not be in direct contact with one another.

Therefore, because the copper wiring 11 is not exposed to a NH₃ gas when the cap film 13 is formed, it may be possible to prevent or reduce the stress corrosion cracking from occurring in the copper wiring 11. Hence, reliability in the copper wiring 11 and a Cu via connected to the copper wiring 11 may be enhanced. By providing a SiC film having a sufficient thickness as the barrier film 12, the surface of the copper wiring 11 may be prevented from being exposed to the NH₃ gas when forming the cap film 13. The barrier film 12 should preferably be thin enough that an amount of gas separated by forming the barrier film 12 is not sufficient to cause problems, such as the contamination of photoresist.

In other words, it may be possible to obtain a cap film 13 having a low permittivity and prevent contaminated photoresist from being produced during the formation of a via. Further, the copper wiring 11 may be prevented from being exposed to a NH₃ gas used as a film forming gas, even if the cap film 13 includes a SiCN film formed over a surface of the copper wiring 11.

A wiring structure described above may also be formed in a dual damascene process, which produces the wiring and via together, or in a single damascene process, which separately produces the wiring and via.

It is understood that the embodiments described above are exemplary and the present invention should not be limited to those embodiments. Specific structures should not be limited to the described embodiments.

For example, a trimethylsilane gas, He gas, and NH₃ gas may be used as gases to form a cap film 13 in the above-described embodiment. However, an argon gas (Ar) or nitrogen gas (N₂) may be used instead of the He gas, as just two examples.

As described above, according to the embodiments, because a cap film for prevention of copper diffusion is formed between a wiring made of copper or a copper alloy and an insulation film covering an upper surface of a wiring, copper diffusion may be prevented. Also, because the cap film is formed on a barrier film covering the upper surface of the wiring, the wiring and the cap film may not be in direct contact. Thus, even if a SiCN film is included in the cap film for a wiring made of copper or a copper alloy, a NH₃ gas, which is a source gas for the SiCN film, does not contact the wiring. In this way, stress corrosion cracking in the wiring may be prevented.

While various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A semiconductor device, comprising:
a wiring structure in which an upper surface of a wiring made of a copper containing film is covered with an insulation film, wherein a barrier film is formed covering the upper surface of the wiring and between the wiring and a cap film for preventing copper diffusion.

2. The semiconductor device of claim 1, wherein:
the barrier film is an exposure prevention film which prevents the wiring from being exposed to a film forming gas for the cap film.

3. The semiconductor device of claim 1, wherein:
the cap film includes an SiCN film.

4. The semiconductor device of claim 3, wherein:
the SiCN film is a film formed with a trimethylsilane gas, NH₃ gas, and a third gas, the third gas being selected from the group consisting of helium gas (He), nitrogen gas (N₂), and argon gas (Ar).

5. The semiconductor device of claim 1, wherein:
the barrier film is a film formed without using NH₃ gas.

6. The semiconductor device of claim 5, wherein:
the barrier film includes a SiC film.

7. The semiconductor device of claim 1, further including:
a multilayer wiring structure including a plurality of wiring layers made of a copper containing film, with each wiring layer separated by a respective interlayer insulation film.

8. A method of producing a semiconductor device having a wiring structure in which an upper surface of a wiring made of copper or a copper alloy is covered with an insulation film, comprising the step of:
forming a cap film, for prevention of copper diffusion, between the wiring and the insulation film, and over a barrier film covering the upper surface of the wiring.

9. The method of producing the semiconductor device of claim 8, further including:
a step of forming the barrier film without using a NH₃ gas after the wiring film is formed.

10. The method of producing the semiconductor device of claim 8, wherein:
the barrier film includes an SiC film.

11. The method of producing the semiconductor device of claim 8, wherein:
the step of forming the cap film includes using a trimethylsilane gas, NH₃ gas, and third gas after the barrier film is formed, the third gas being selected from the group consisting of helium gas (He), nitrogen gas (N₂), and argon gas (Ar).

12. The method of producing the semiconductor device of claim 11, wherein:
the cap film is formed by introducing the NH₃ gas after the barrier film is formed by using the trimethylsilane gas and the third gas.

13. The method of producing the semiconductor device of claim 11, wherein:
the cap film includes a SiCN film.

14. The method of producing the semiconductor device of claim 8, wherein the barrier film and the cap film are formed after the wiring is formed and further including the steps of:
a series of processes for forming layers of wirings, each layer of wiring covered by an interlayer insulation film and including a step of forming a cap film, for prevention of copper diffusion, over a barrier film covering an upper surface of the layer of wiring.

15. A method of producing a semiconductor device, including the steps of:
forming a first wiring layer made of a copper containing film within a first interlayer insulation film;
forming a first barrier film over an upper surface of the first wiring layer;
forming a first cap film for preventing copper diffusion over the first barrier film; and
forming a second interlayer insulation film over the first cap film.

16. The method of producing the semiconductor device of claim 15, wherein:
the step of forming the first barrier film does not include using a NH₃ gas.

17. The method of producing the semiconductor device of claim 15, wherein:
the first barrier film includes a SiC film; and
the first cap film includes a SiCN film.

18. The method of producing the semiconductor device of claim 15, wherein:
the step of forming the first cap film includes using a trimethylsilane gas, NH₃ gas, and a third gas after the first barrier film is formed, the third gas being selected from the group consisting of helium gas (He), nitrogen gas (N₂), and argon gas (Ar).

19. The method of producing the semiconductor device of claim 18, wherein:
the first cap film is formed by introducing the NH₃ gas after the first barrier film is formed by using the trimethylsilane gas and the third gas.

20. The method of producing the semiconductor device of claim 15, further including the steps of:
forming a second wiring layer made of a copper containing film within a third interlayer insulation film over the second interlayer insulation film;
forming a second barrier film over an upper surface of the second wiring layer; and
forming a second cap film for preventing copper diffusion over the second barrier film.
